(19) United States
(12) Patent Application Publication
(10) Pub. No.: US 2008/0045014 A1
(43) Pub. Date: Feb. 21, 2008

(54) COMPLEX CHEMICAL MECHANICAL POLISHING AND METHOD FOR MANUFACTURING SHALLOW TRENCH ISOLATION STRUCTURE

(75) Inventors: Yen-Chu Chen, Nantou County (TW); Hsin-Kun Chu, Hsinchu County (TW); Teng-Chun Tsai, Hsinchu (TW); Chia-Hsi Chen, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: United Microelectronics Corp., Hsinchu (TW)

(21) Appl. No.: 11/465,457

(22) Filed: Aug. 18, 2006

(51) Int. Cl. H01L 21/302; H01L 21/461

(52) U.S. Cl. 438/691

(57) ABSTRACT

A complex chemical mechanical polishing process for planarizing a structure. The process comprises steps of performing a main polishing process with a first polishing rate, wherein a slurry is provided. An assisted polishing process is then performed to planarizing the structure. The assisted polishing process comprises steps of providing the slurry in a first period of time and then providing a solvent and performing a polishing motion of a second polishing rate in a second period of time. The second polishing rate is slower than the first polishing rate.

### BACKGROUND OF THE INVENTION

1. Field of Invention

The present invention relates to a chemical mechanical polishing process. More particularly, the present invention relates to a complex chemical mechanical polishing process.

2. Description of Related Art

In the semiconductor process, with the decrease of the device size, the resolution of the photolithography is increased. Furthermore, with the decrease of the depth of focus, the demand for having a more even surface of the wafer is high.

Currently, the wafer planarization is accomplished by the chemical mechanical polishing (CMP) process. Typically, the CMP process, especially the traditional silica-based shallow-trench-isolation CMP (STI-CMP) process, possesses the advantages including low cost, high polishing rate and high planarization efficiency.

However, in the STI-CMP process, there still exists some drawbacks comprising, for example, the under polishing issue caused by low selective ratio of oxide to nitride or the dishing phenomenon caused by over polishing. Conventionally, in order to prevent the drawbacks, the reserve mask (RM) is used to assist the manufacturing process. Nevertheless, by assisting with the reserve mask, it is necessary to perform an additional photolithography-and-etching process to form a reverse phase mask. Hence, the manufacturing process becomes more complicated and the cost is increased as well. In addition, the STI-CMP process also confronts with the problems of being hard to control the thickness and uniformity of the oxide layer of the STI so that the reliability of the manufacturing process is decreased.

### SUMMARY OF THE INVENTION

Accordingly, at least one objective of the present invention is to provide a complex chemical mechanical polishing process capable of preventing the problems of under polishing or over polishing. Therefore, the uniformity of the wafer surface is increased and the reliability of the manufacturing process is increased as well.

At least another objective of the present invention is to provide method of forming a shallow trench isolation structure. By using the method of the present invention, the dishing phenomenon can be prevented so as to increase the planarization of the shallow trench isolation structure and the reliability of the manufacturing process.

To achieve these and other advantages and in accordance with the purpose of the invention, as embodied and broadly described herein, the invention provides a complex chemical mechanical polishing process for planarizing a structure. The process comprises steps of performing a main polishing process with a first polishing rate, wherein a slurry is provided. An assisted polishing process is then performed to planarizing the structure. The assisted polishing process comprises steps of providing the slurry in a first period of time and then providing a solvent and performing a polishing motion of a second polishing rate in a second period of time. The second polishing rate is slower than the first polishing rate.

In the present invention, the solvent includes deionized water. Moreover, the first period of time is of about 0˜20 seconds and the second period of time is of about 2˜20 seconds. Furthermore, the slurry includes a high selectivity slurry such as a cerium oxide-contained solution.

The present invention also provides a method of forming a shallow trench isolation structure. The method comprises steps of providing a substrate having a patterned mask layer formed thereon, wherein a trench is located in the substrate and the patterned mask layer exposes the trench. Thereafter, a dielectric layer is formed over the substrate to fill the trench. Then, a main polishing process with a first polishing rate is performed to remove a portion of the dielectric layer. An assisted polishing process is performed to remove the dielectric layer and a portion of the mask layer. The assisted polishing process comprises steps of providing a slurry in a first period of time and then providing a solvent and performing a polishing motion of a second polishing rate in a second period of time. The second polishing rate is slower than the first polishing rate. Further, the mask layer is removed.

In the present invention, the solvent includes deionized water. Moreover, the first period of time is of about 0˜20 seconds and the second period of time is of about 2˜20 seconds. Furthermore, the slurry includes a high selectivity slurry such as a cerium oxide-contained solution.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flowchart illustrating a complex chemical mechanical polishing process according to a preferred embodiment of the invention.

FIG. 2A through FIG. 2G are cross-sectional views showing a method of forming a shallow trench isolation structure according to a preferred embodiment of the invention.

### DESCRIPTION OF THE PREFERRED EMBODIMENTS

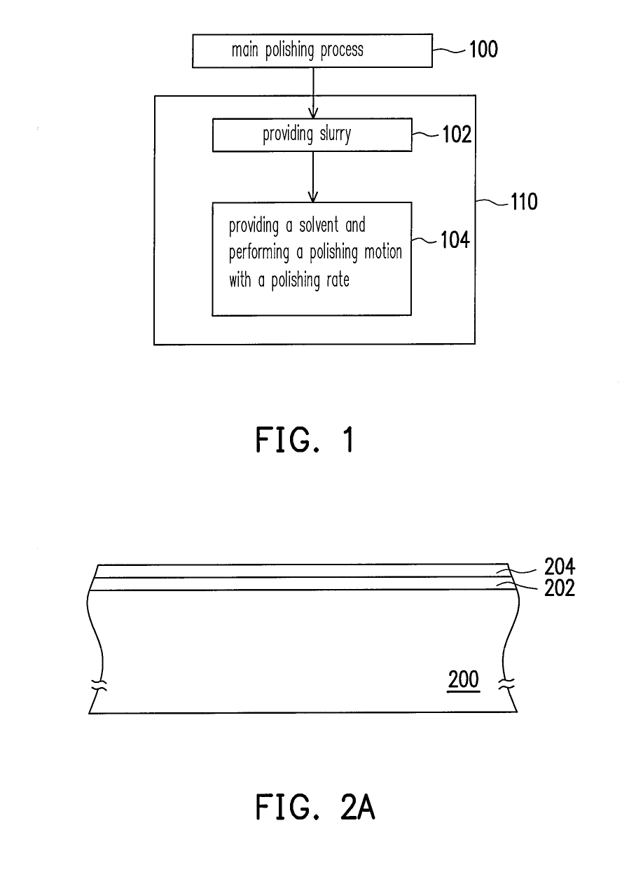

FIG. 1 is a flowchart illustrating a complex chemical mechanical polishing process according to a preferred embodiment of the invention.

As shown in FIG. 1, a main polishing process (step 100) is performed. In the main polishing process comprises steps of providing a slurry and performing a polishing motion of a polishing rate V1. The slurry can be, for example, a high selectivity slurry (HSS). The HSS can be, for example, a cerium oxide-contained solution.

The main polishing process mentioned above is the same as the conventional chemical mechanical polishing process. The purpose of the main polishing process is to remove most of material which is predetermined to be removed away in a short period of time. In order to increase the polishing rate, the main polishing process is stopped once the interface between the different materials is exposed although some of the material predetermined to be removed away still remain on the wafer.

After the main polishing process (step 100) is performed, an assisted polishing process (step 110) is performed. Initially, in the assisted polishing process, a slurry is provided (step 102) without performing a polishing motion in a period of time Ti. Thereafter, in the step 104, a solvent is provided and a polishing motion with a polishing rate V2 is performed simultaneously in a period of time T2.

In the step 102, T1 can be, for example, of about 0˜20 seconds and the slurry can be, for example, the same as the one used in the main polishing process. Further, the slurry used in the step 102 can be, for example, HSS such as a cerium oxide-contained solution. Furthermore, in the step 104, T2 can be, for example, of about 2˜20 seconds and the solvent can be, for example, deionized water (DIW). In addition, the polishing rate V2 is slower than the polishing rate V1.

Notably, in the conventional chemical mechanical polishing process, after the main polishing process stops, if the chemical mechanical polishing machine is re-started again to perform another polishing process, the initial polishing rate is high because the polishing parameters is unchanged. Hence, the over polishing happens and the reliability of the manufacturing process is affected. However, in the assisted polishing process of the present invention, the slurry is provided without performing any polishing motion and then the polishing motion is started after the solvent is applied. Therefore, the polishing rate in the assisted polishing process is slower than the polishing rate of the main polishing process so that the over polishing can be avoided and the dishing problem caused by the over polishing can be overcome. In addition, the assisted polishing process can be also applied to the rework process of the chemical mechanical polishing process to increase the planarization of the wafer. Altogether, the complex chemical mechanical polishing process of the present invention can ensure that the material predetermined to be removed away can be completely polished away and also can prevent the dishing phenomenon caused by over polishing. Therefore, the reliability of the manufacturing process is increased.

A method of forming a shallow trench isolation structure with using the complex chemical mechanical polishing process is described below. Although the complex chemical mechanical polishing process applied to the formation of the shallow trench isolation structure is recited below, the complex chemical mechanical polishing process is not limited by being applied to the formation of the shallow trench isolation structure. The complex chemical mechanical polishing process can be applied to any other semiconductor process which needs to use chemical mechanical polishing process.

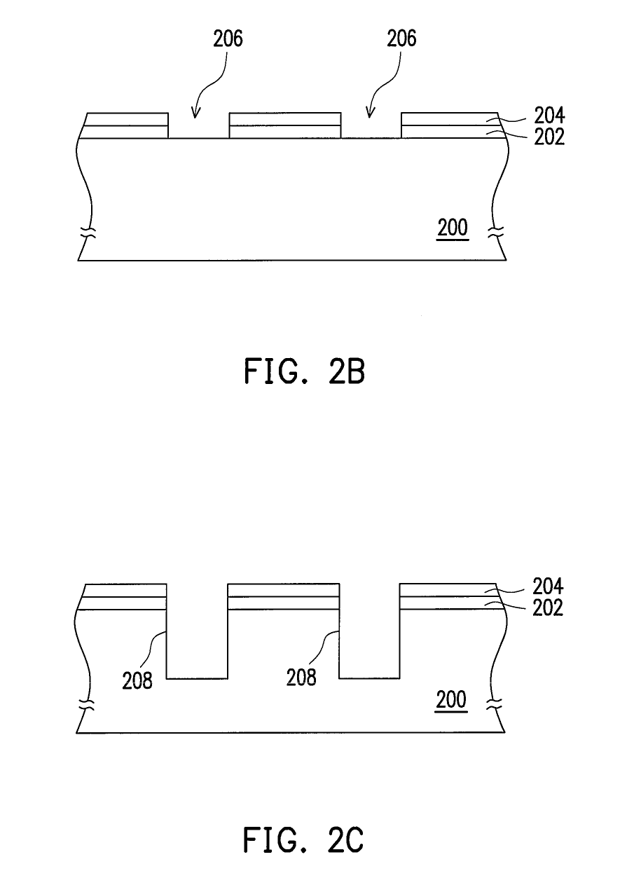

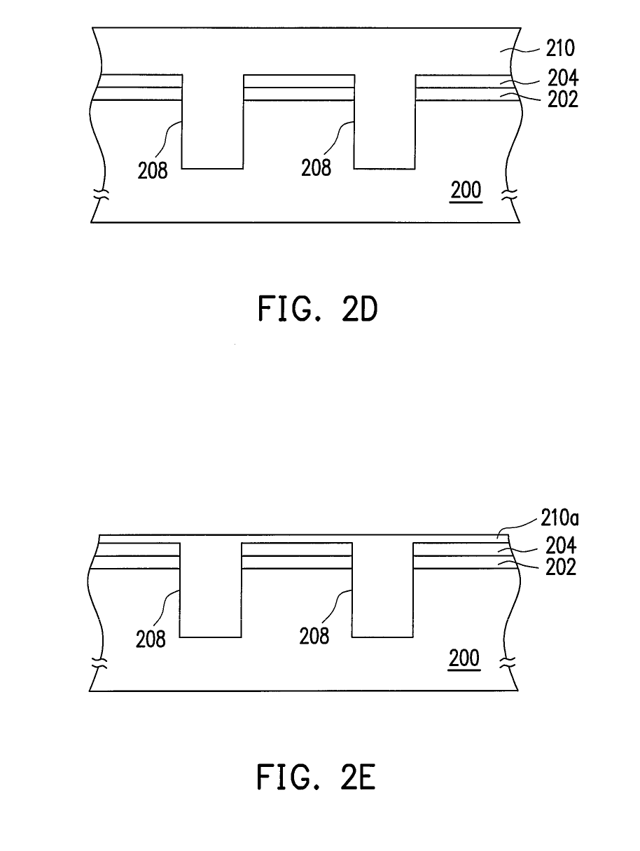

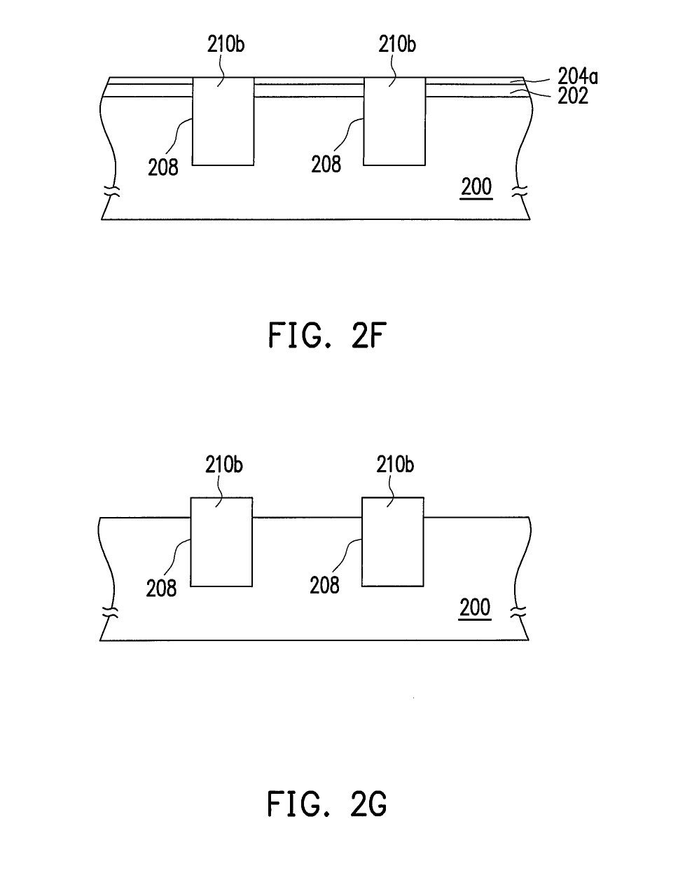

FIG. 2A through FIG. 2G are cross-sectional views showing a method of forming a shallow trench isolation structure according to a preferred embodiment of the invention.

As shown in FIG. 2A, a substrate 200 is provided. The substrate 200 can be, for example, a silicon substrate. A pad oxide layer 202 and a mask layer 204 are formed over the substrate 200 successively. The pad oxide 202 can be, for example, formed from silicon oxide by thermal oxidation. Further, the mask layer 204 can be, for example, formed from silicon nitride by chemical vapor deposition.

As shown in FIG. 2B, an opening 206 is formed in the mask layer 204 and the pad oxide layer 202. The method for forming the opening 206 comprises step of forming a patterned photoresist (not shown) over the mask layer 204 and etching away a portion of the mask layer 204 and the pad oxide layer 202 by using the patterned photoresist as a mask until a portion of the substrate 200 is exposed.

As shown in FIG. 2C, a portion of the substrate 200 is removed to form a trench 208 by using the mask layer 204 as a mask. The method for removing the portion of the substrate 200 can be, for example, an etching process.

As shown in FIG. 2D, a dielectric layer 210 is formed over the substrate 200 to fill the trench 208. The dielectric layer 210 can be formed from silicon oxide by chemical vapor deposition.

As shown in FIG. 2E, a main polishing process is performed to remove a portion of the dielectric layer 210. The polished amount of the dielectric layer is related to the process window. The polishing mechanism of the main polishing process is the same as that of the conventional chemical mechanical polishing process. In the main polishing process, a slurry is provided and a polishing motion is performed with a polishing rate. The slurry can be, for example, a HSS such as a cerium oxide-contained solution.

As shown in FIG. 2F, after the main polishing process is performed, an fassisted polishing process is performed to remove a portion of the dielectric layer 210a and a portion of the mask layer 204. Initially, in the assisted polishing process, a slurry is provided without performing a polishing motion in a period of time T1. Thereafter, a solvent is provided and a polishing motion with another polishing rate is performed simultaneously in a period of time T2. The slurry used in the assisted polishing process is the same as the slurry used in the main polishing process. The slurry can be, for example, a HSS such as a cerium oxide-contained solution.

T1 can be, for example, of about 0˜20 seconds and T2 can be, for example, of about 2˜20 seconds. T1 and T2 are related to the process window and can be adjusted with the variation of the process window.

As shown in FIG. 2G, the mask layer 204a and the pad oxide layer 202 are removed to form a shallow trench isolation structure 210b. The method for removing the mask layer 204a and the pad oxide layer 202 can be, for example, an isotropic etching process. Since a portion of the mask layer 204 is removed during the previous assisted polishing process, it can be sure that no dielectric material remains over the mask layer 204a. Therefore, the situation benefits the removal of the mask layer 204a.

In the present invention, there is no over polishing issue as the one happening in the conventional chemical mechanical polishing process so that the manufacturing reliability is increased. Other than that the material which is predetermined to be polished away can be totally removed, there is no dishing phenomenon by applying the present invention so that the planarization of the wafer is increased. In addition, the assisted polishing process can be also applied to the rework process of the chemical mechanical polishing process to increase the planarization of the wafer. Furthermore, the solvent used in the assisted polishing process can be the chemical solvent used in the conventional process so that the cost is reduced.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A complex chemical mechanical polishing process for planarizing a structure, comprising:
performing a main polishing process with a first polishing rate, wherein a slurry is provided; and
performing an assisted polishing process to planarizing the structure, wherein the assisted polishing process comprises:
providing the slurry in a first period of time; and
providing a solvent and performing a polishing motion of a second polishing rate in a second period of time, wherein the second polishing rate is slower than the first polishing rate.

2. The complex chemical mechanical polishing process of claim 1, wherein the solvent includes deionized water.

3. The complex chemical mechanical polishing process of claim 1, wherein the first period of time is of about 0˜20 seconds.

4. The complex chemical mechanical polishing process of claim 1, wherein the second period of time is of about 2˜20 seconds.

5. The complex chemical mechanical polishing process of claim 1, wherein the slurry includes a high selectivity slurry.

6. The complex chemical mechanical polishing process of claim 1, wherein the slurry includes a cerium oxide-contained solution.

7. A method of forming a shallow trench isolation structure, comprising:
providing a substrate having a patterned mask layer formed thereon, wherein a trench is located in the substrate and the patterned mask layer exposes the trench;
forming a dielectric layer over the substrate to fill the trench;
performing a main polishing process with a first polishing rate to remove a portion of the dielectric layer;
performing an assisted polishing process to remove the dielectric layer and a portion of the mask layer, wherein the assisted polishing process comprises:
providing a slurry in a first period of time; and
providing a solvent and performing a polishing motion of a second polishing rate in a second period of time, wherein the second polishing rate is slower than the first polishing rate; and
removing the mask layer.

8. The method of claim 7, wherein the solvent includes deionized water.

9. The method of claim 7, wherein the first period of time is of about 0˜20 seconds.

10. The method of claim 7, wherein the second period of time is of about 2˜20 seconds.

11. The method of claim 7, wherein the slurry includes a high selectivity slurry.

12. The method of claim 7, wherein the slurry includes a cerium oxide-contained solution.
